(19) United States
(12) Patent Application Publication
(10) Pub. No.: US 2019/0267463 A1
(43) Pub. Date: Aug. 29, 2019

(54) LOW-K DIELECTRIC INNER SPACER FOR GATE ALL AROUND TRANSISTORS

(71) Applicant: INTERNATIONAL BUSINESS MACHINES CORPORATION, Armonk, NY (US)

(72) Inventors: Robin Hsin Kuo Chao, Cohoes, NY (US); Choonghyun Lee, Rensselaer, NY (US); Jingyun Zhang, Albany, NY (US); Chun Wing Yeung, Niskayuna, NY (US)

(21) Appl. No.: 15/908,001

(22) Filed: Feb. 28, 2018

(51) Int. Cl. H01L 29/423; H01L 29/06; H01L 29/66; H01L 29/78

(52) U.S. Cl. CPC H01L 29/42392; H01L 29/0669; H01L 2029/7858; H01L 29/785; H01L 29/66795

(57) ABSTRACT

Semiconductor devices and methods of forming the same include forming a stack of alternating channel layers and sacrificial layers. The sacrificial layers are recessed relative to the channel layers. Inner spacers are formed at ends of the sacrificial layers with a process that preferentially forms dielectric material on the sacrificial layers relative to the channel layers. Source and drain structures are formed at ends of the channel layers. The sacrificial layers are etched away to expose surfaces of the channel layers. A gate stack is formed on and around the channel layers.

### BACKGROUND

### Technical Field

The present invention generally relates to transistor fabrication and, more particularly, to the fabrication of gate all around nanosheet and nanowire transistors that make use of low-k dielectric inner spacers between vertically adjacent channels.

### Description of the Related Art

Nanosheet transistor devices (such as, e.g., nanosheet gate all around field effect transistors (FETs) may make use of nitride-based dielectric inner spacers to improve yield and to reduce parasitic capacitance. However, such nitride structures may have an undesirably high dielectric constant and, furthermore, often suffer from capillary effects that cause the inner spacers to take on a crescent shape that undercuts too far into the channel.

### SUMMARY

A method of forming a semiconductor device includes forming a stack of alternating channel layers and sacrificial layers. The sacrificial layers are recessed relative to the channel layers. Inner spacers are formed at ends of the sacrificial layers with a process that preferentially forms dielectric material on the sacrificial layers relative to the channel layers. Source and drain structures are formed at ends of the channel layers. The sacrificial layers are etched away to expose surfaces of the channel layers. A gate stack is formed on and around the channel layers.

A method of forming a semiconductor device includes forming a stack of alternating channel layers and sacrificial layers. The sacrificial layers are recessed relative to the channel layers. The sacrificial layers and channel layers are oxidized with a low partial pressure of oxygen to form inner spacers at ends of the sacrificial layers from silicon dioxide with a purity between about 95% and about 100%. Source and drain structures are formed at ends of the channel layers. The sacrificial layers are etched away to expose surfaces of the channel layers. A gate stack is formed on and around the channel layers.

A semiconductor device includes vertically stacked channel layers. Inner spacers are positioned between vertically adjacent channel layers. A gate stack is formed between and around the channel layers. An interface between each inner spacer and the gate stack is flat.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional view of a step in the formation of a nanosheet field effect transistor (FET) using low-k inner spacers that depicts a stack of alternating channel layers and sacrificial layers in accordance with an embodiment of the present invention;

FIG. 2 is a cross-sectional view of a step in the formation of a nanosheet FET using low-k inner spacers that depicts the formation of a dummy gate and an etch of the stack of layers around the dummy gate in accordance with an embodiment of the present invention;

FIG. 3 is a cross-sectional view of a step in the formation of a nanosheet FET using low-k inner spacers that depicts recessing the sacrificial layers relative to the channel layers in accordance with an embodiment of the present invention;

FIG. 4 is a cross-sectional view of a step in the formation of a nanosheet FET using low-k inner spacers that depicts the formation of dielectric material with a process that preferentially forms dielectric material on the sacrificial layers in accordance with an embodiment of the present invention;

FIG. 5 is a cross-sectional view of an optional step in the formation of a nanosheet FET using low-k inner spacers that depicts nitridating the dielectric material in accordance with an embodiment of the present invention;

FIG. 6 is a cross-sectional view of a step in the formation of a nanosheet FET using low-k inner spacers that depicts etching back the dielectric material to form inner spacers and to expose end surfaces of the channel layers in accordance with an embodiment of the present invention;

FIG. 7 is a cross-sectional view of a step in the formation of a nanosheet FET using low-k inner spacers that depicts the formation of source and drain regions from exposed surfaces of the channel layers in accordance with an embodiment of the present invention;

FIG. 8 is a cross-sectional view of a step in the formation of a nanosheet FET using low-k inner spacers that depicts selectively etching away the sacrificial layers to expose the channel layers in accordance with an embodiment of the present invention;

FIG. 9 is a cross-sectional view of a step in the formation of a nanosheet FET using low-k inner spacers that depicts the formation of a gate stack between and around the channel layers in accordance with an embodiment of the present invention; and

FIG. 10 is a block/flow diagram of a method of forming a nanosheet FET using low-k inner spacers in accordance with an embodiment of the present invention.

### DETAILED DESCRIPTION

Embodiments of the present invention provide gate all around field effect transistors (FETs) that make use of low-k dielectric spacers formed from oxides, oxynitrides, or other appropriate dielectric materials. Furthermore, the interface between the inner spacers and the channel structure(s) has a relatively flat, straight surface that does not cut into the channel structure(s). These inner spacers are furthermore formed with a high degree of purity in their material composition.

To accomplish this, the low-k dielectric is thermally oxidized in a manner that selectively forms dielectric material on particular structures due to, e.g., favorable thermodynamics. In one specific embodiment, silicon germanium sacrificial layers are recessed and the low-k dielectric material is selectively formed on the recessed sacrificial layers, with relatively little low-k dielectric material being formed on the ends of the channel layers. This difference in rate of formation of the low-k dielectric layer makes it possible to subsequently expose the channel ends for source and drain formation without substantially damaging the inner spacers.

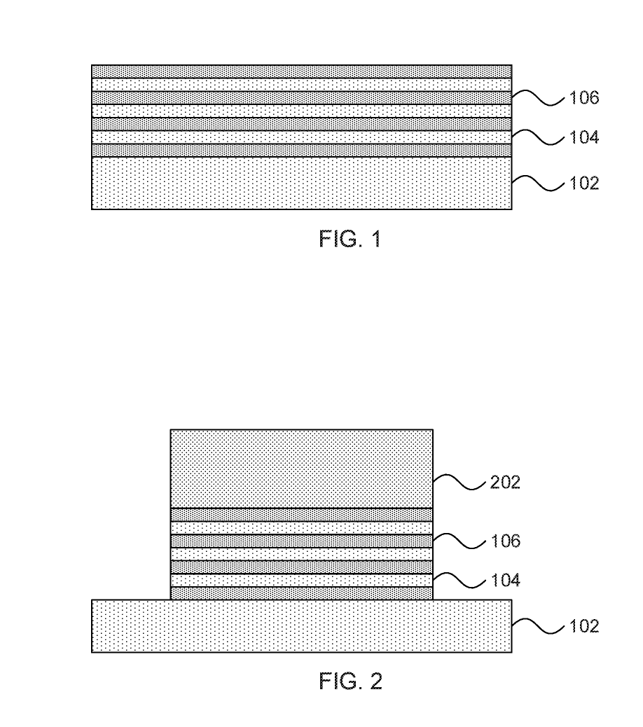

Referring now to the drawings in which like numerals represent the same or similar elements and initially to FIG. 1, a step in the formation of a FET is shown. A semiconductor substrate 102 is layered with alternating layers of channel material 104 and sacrificial material 106. The semiconductor substrate 102 may be a bulk-semiconductor substrate. It should be understood that the stack of channel layers 104 and sacrificial layers 106 can be sectioned into device regions, although only one such device region is shown herein. It is specifically contemplated that the alternating layers of channel material 104 and sacrificial material 106 are formed as sheets of material. It should be understood that, although nanosheet structures are handled specifically herein, the present embodiments may be applied to create nanowire or other structures as well.

In one specific embodiment, it is contemplated that the layers of channel material 104 may have a thickness between about 5 nm and about 10 nm and that the layers of sacrificial material 106 may have a thickness between about 7 nm and about 15 nm. As used herein, the term “nanosheet” refers to a structure that has a ratio of its cross-sectional width to its cross-sectional height greater than about 2:1, whereas the term “nanowire” refers to a structure that has a ratio of its cross-sectional width to its cross-sectional height less than about 2:1.

In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate.

It is specifically contemplated that the alternating layers 104 and 106 are formed from different materials. In one particular embodiment, the layers of channel material 104 may be formed from, e.g., a silicon-containing semiconductor, with silicon itself being specifically contemplated, and the layers of sacrificial material may be formed from a silicon germanium composite, with a germanium concentration of about 40%. In one particular embodiment, the layers of channel material 104 may be about 9 nm thick and the layers of sacrificial material may be about 12 nm thick, but it should be understood that other thicknesses may be used in accordance with design needs and fabrication process limitations.

The layers of channel material and sacrificial material 104 and 106 may be formed on the substrate 102 by any appropriate deposition process. For example, the alternating layers may be formed by alternating deposition processes including, e.g., chemical vapor deposition (CVD), physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

Referring now to FIG. 2, a step in the formation of a FET is shown. A dummy gate 202 or other sacrificial structure is formed over the stack of alternating layers. It is specifically contemplated that the dummy gate 202. It is specifically contemplated that the dummy gate 202 may be formed from any material that is selectively etchable with respect to the channel material and the sacrificial material.

After formation of the dummy gate 202, the stack of alternating layers is etched down in regions not covered by the dummy gate 202. This etch can be performed using an anisotropic etch such as reactive ion etching (RIE). The etch can be performed in a single etch that removes material from both the channel layers 104 and the sacrificial layers 106 or may, alternatively, be performed using alternating etching processes that selectively affect the channel layers 104 and the sacrificial layers 106 in turn. As used herein, the term “selective” in reference to a material removal process denotes that the rate of material removal for a first material is greater than the rate of removal for at least another material of the structure to which the material removal process is being applied.

RIE is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point of the present invention include ion beam etching, plasma etching or laser ablation.

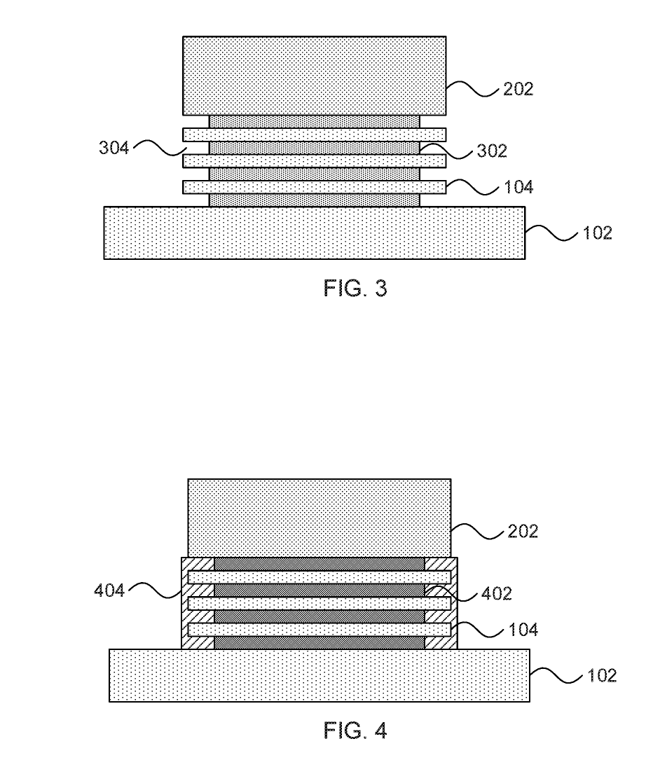

Referring now to FIG. 3, a step in the formation of a FET is shown. The layers of sacrificial material 106 are etched back relative to the layers of channel material 104 using a selective isotropic etch such as a wet or dry chemical etch. In one particular embodiment, hydrochloric acid Standard Clean 1 (“SC1,” also known colloquially as an “RCA® clean”) may be used to selectively etch silicon germanium material while leaving silicon layers relatively unaffected. The etch produces recesses 304 that may in one particular embodiment be about 6 nm deep.

Referring now to FIG. 4, a step in the formation of a FET is shown. A dielectric layer 404 is selectively grown on the exposed portions of the recessed layers of sacrificial material 302. It is specifically contemplated that an oxidation process may be used to form silicon dioxide. Formation of the dielectric material on the recessed silicon germanium is thermodynamically favored over formation of the dielectric material on the exposed portions of channel material 104, with a growth ratio of about 7:1. Thus, for every nanometer of dielectric growth from the channel layers 104, there will be seven nanometers of dielectric growth from the recessed sacrificial layers 302, filling the recesses 304 and bringing the surfaces roughly into line.

The oxidation process condenses silicon out of the silicon germanium layers, resulting in an effective increase in the concentration of germanium in the recessed sacrificial layers 106. In particular, in an environment having a low partial pressure of oxygen (e.g., about 0.076 Torr) the lower Gibbs free energy of silicon results in selective oxidation of the silicon in silicon germanium. At a given oxidation temperature, if the partial pressure of oxygen is high enough, germanium precipitates in the oxidation process and forms a mixture of silicon dioxide and germanium dioxide, which is physically and electrically unstable. If the partial pressure of oxygen is fixed below about 0.1 Torr and oxidation temperature is between about 400° C. and about 600° C., then the oxidation of the channel layers 104 can be avoided, as silicon oxidizes less at low temperatures. This results in the different rates of silicon dioxide formation on the surfaces of the channel layers 104 and the recessed sacrificial layers 106.

Thus, in an embodiment where the sacrificial material starts with a germanium concentration of about 40%, after the condensation process the recessed sacrificial layers 402 may have a germanium concentration of about 60%. This advantageously increases the etch selectivity between the condensed layers of sacrificial material 402 and the layers of channel material 104. The oxidation process smooths any crescent shape that may have been formed by previous steps, producing a flat interface.

It should be understood that the dielectric layer 404 can be formed with a very high degree of material purity in this process. In embodiments where the dielectric layer 404 is formed from silicon dioxide on a silicon germanium surface, the material of the dielectric layer 404 will be between 95% and 100% pure silicon dioxide if the germanium concentration in the recessed sacrificial layers 302 is about 40%. If the germanium concentration of the recessed sacrificial layers 302 is lower than 40%, then the material of the dielectric layer 404 will have be between about 99% and about 100% pure silicon dioxide. These purities are significantly higher than would otherwise be achievable.

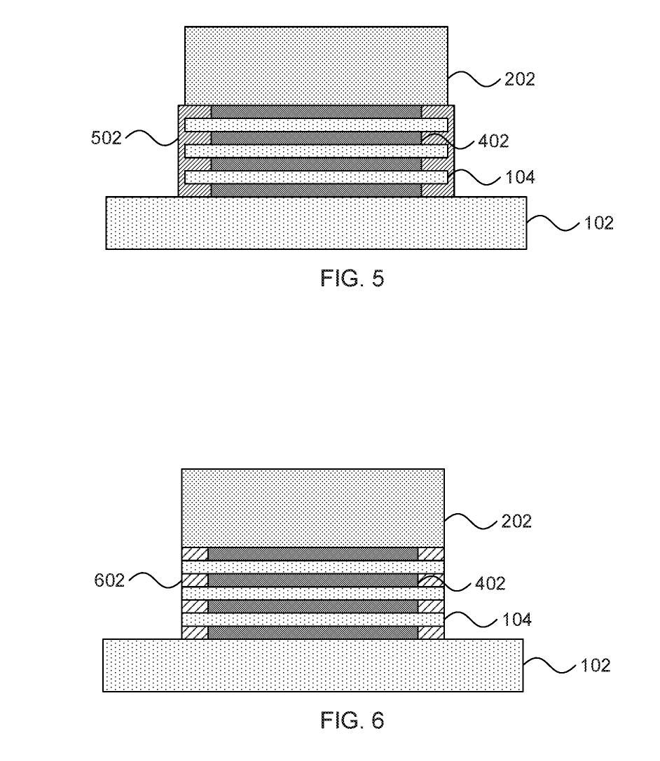

Referring now to FIG. 5, an optional step in the formation of a FET is shown. The dielectric layer 404 may optionally be nitridated using, for example, a thermal or plasma nitridation process. The nitridation process may be used to, for example, alter the dielectric constant of the dielectric layer 404. In an embodiment where the dielectric layer is formed from silicon dioxide (having a dielectric constant of about 3.9), nitridation will produce silicon oxynitride (having a dielectric constant of about 5). In one specific embodiment, the nitridation may be performed at a temperature of about 700° C. and a pressure of about 740 Torr. This nitridation process can be advantageous in some embodiments because silicon oxynitride is more stable than silicon dioxide in subsequent processes. If this optional step is used, then the silicon oxynitride will have a purity similar to that for silicon dioxide inner spacers as discussed above.

Referring now to FIG. 6, a step in the formation of a FET is shown. The dielectric layer 404 is etched back to expose the ends of the layers of channel material 104. This process separates the dielectric layer 404 into inner spacers 602, each in a separate recess 304. Any appropriate selective etch may be used. In some embodiments, a timed, isotropic, wet or dry chemical etch, such as by dilute hydrofluoric acid, may be used to selectively remove material from the dielectric layers 304 while leaving the inner spacers 602 intact. In other embodiments, an anisotropic, directional etch may be used to remove dielectric material from the sides of the stack of layers without etching laterally into the inner spacers 602.

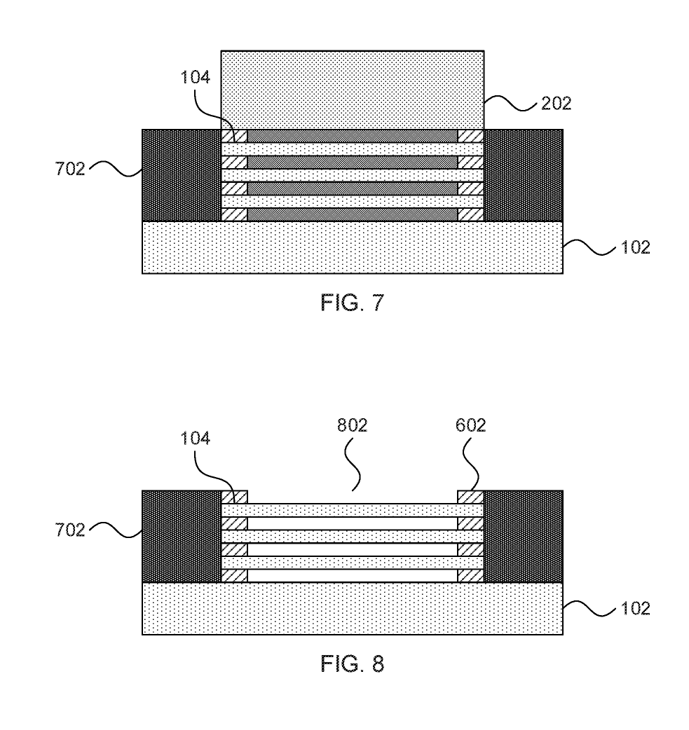

Referring now to FIG. 7, a step in the formation of a FET is shown. Source and drain regions 702 are formed on respective exposed ends of layers of channel material 104. It is specifically contemplated that the source and drain regions 702 may be formed by epitaxial growth, though it should be understood that other deposition processes may be employed instead. The source and drain regions 702 may be formed from, e.g., a doped semiconductor material such as p-type or n-type doped silicon, but it should be understood that any appropriately doped semiconductor material may be used instead. The material formed at the sides of each of the layers of channel material 104 merges together to form a single source/drain structure. Although these structures are shown as being rectangular in shape for simplicity, it should be understood that the source/drain structures 702 will take on a shape in accordance with the process of their formation and, in the case of epitaxial growth, in accordance with the crystal orientation.

The term “epitaxial growth” means the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation. In the present embodiments the epitaxial growth process may be selective to the channel material, such that no material is grown on the surfaces of the dummy gate 202 or the inner spacers 602.

Source/drain epitaxy can be done by ultrahigh vacuum chemical vapor deposition (UHVCVD), rapid thermal chemical vapor deposition (RTCVD), metalorganic chemical vapor deposition (MOCVD), low-pressure chemical vapor deposition (LPCVD), limited reaction processing CVD (LRPCVD), molecular beam epitaxy (MBE), or any other appropriate process. Epitaxial materials may be grown from gaseous or liquid precursors. Epitaxial materials may be grown using vapor-phase epitaxy (VPE), molecular-beam epitaxy (MBE), liquid-phase epitaxy (LPE), or other suitable process. Epitaxial silicon, silicon germanium SiGe, and/or carbon-doped silicon (Si:C) silicon can be doped during deposition (in-situ doped) by adding dopants, n-type dopants (e.g., phosphorus or arsenic) or p-type dopants (e.g., boron or gallium), depending on the type of transistor. The dopant concentration in the source/drain can range from about 1×10¹⁹ cm⁻³ to about 2×10²¹ cm⁻³, or preferably between 2×10²⁰ cm⁻³ and 1×10²¹ cm⁻³. When Si:C is epitaxially grown, the Si:C layer may include carbon in the range of 0.2 to 3.0%. When silicon germanium is epitaxially grown, the silicon germanium may have germanium content in the range of 5% to 80%, or preferably between 20% and 60%.

Referring now to FIG. 8, a step in forming a FET is shown. The dummy gate 202 is etched away. The recessed layers of condensed sacrificial material 402 are then also etched away, leaving the top and bottom surfaces of the layers of channel material 104 exposed in gap 802. The layers of channel material 104 remain separated by inner spacers 602 and are supported by their ends. Any appropriate wet or dry chemical etch or etches may be used to remove the dummy gate 202 and the recessed layers of condensed sacrificial material 402. One exemplary etch that may be used is a gaseous hydrochloric acid etch that selectively removes silicon germanium while leaving silicon channel layers relatively untouched.

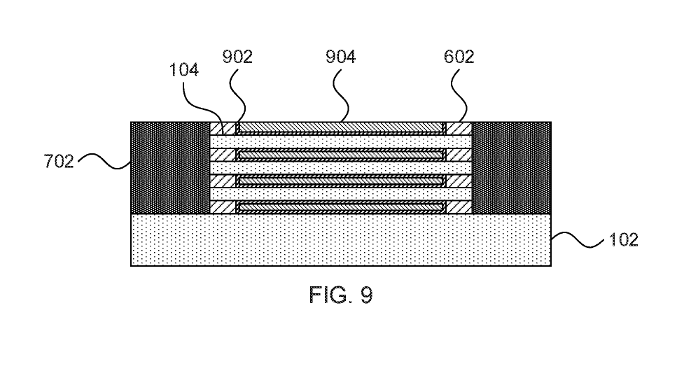

Referring now to FIG. 9, a step in forming a FET is shown. A gate stack is formed from a gate dielectric 902 and a gate conductor 904. The gate dielectric 902 may be formed by any conformal deposition process including, e.g., CVD or ALD and may include any appropriate dielectric material. At this stage, a passivating layer (not shown) may be deposited over the device and electrical contacts (not shown) may be formed to the source and drain structures 702 and to the gate conductor 904.

It is specifically contemplated that the gate dielectric 902 may be formed from a high-k dielectric material, which is defined as a material having a dielectric constant k that is greater than the dielectric constant of silicon dioxide. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k dielectric material may further include dopants such as lanthanum and aluminum.

The gate conductor 904 may be, for example, a metal or metallic conductive material including, e.g., tungsten, nickel, titanium, molybdenum, tantalum, copper, platinum, silver, gold, ruthenium, iridium, rhenium, rhodium, and alloys thereof. The gate conductor may alternatively include a doped semiconductor material such as, e.g., doped polysilicon. When a combination of conductive elements is employed, an optional diffusion barrier material such as tantalum nitride or tungsten nitride may be formed between the conductive materials.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural fogs as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientatations), and the spatially relative descriptors used herein can be interpreted accordingly. In addition, it will also be understood that when a layer eferred to as being “between” two layers, it can be the only layer between the two layers intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

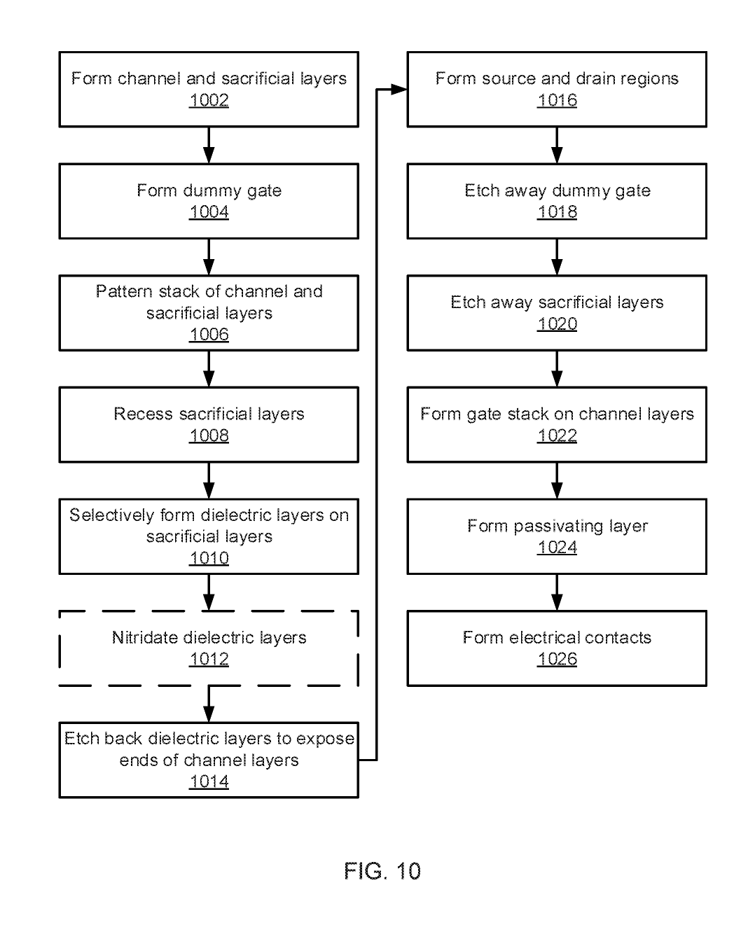

Referring now to FIG. 10, a method of forming a FET is shown. Block 1002 forms the layers of channel material 104 and the layers of sacrificial material 106 on a substrate 102. The layers may be formed by, e.g., epitaxial growth or by any other appropriate deposition process. As noted above, it is specifically contemplated that the channel material may be silicon and that the sacrificial material may be silicon germanium with a germanium concentration of about 40%. Block 1004 forms dummy gate 202 by depositing a layer of dummy gate material (e.g., polysilicon) and using a photolithographic patterning process to define the dummy gate 202 and to etch away remaining dummy gate material. Block 100-6 then patterns the layers of channel material 104 and the layers of sacrificial material 106 using one or more anisotropic etches such as, e.g., an appropriate RIE.

Block 1008 recesses the layers of sacrificial material 106 relative to the layers of channel material 104 using a selective, isotropic etch. Block 1010 then forms dielectric layers 404 on exposed ends of the layers of channel material 104 and the recessed layers of the sacrificial material 302 using a formation process that favors deposition on the recessed layers of sacrificial material 302 (e.g., an oxidation process with a low partial pressure of oxygen). Thus, in embodiments that use silicon as the channel material and silicon germanium as the sacrificial material, deposition from surfaces of the sacrificial material may be accomplished at a rate about seven times greater than deposition from surfaces of the channel material. The dielectric layers 404 that result have a particularly sharp and flat interface with the recessed layers of sacrificial material 302, avoiding the formation of interfaces with a crescent shape. Block 1012 optionally nitridates the dielectric layers 404 using, e.g., an ammonia anneal.

Block 1014 etches back the dielectric layers 404 to expose the ends of the layers of channel material 104. Block 1016 then forms source and drain structures 702 in contact with the ends of the layers of channel material 104 by, for example, epitaxial growth with in situ doping. Block 1018 etches away the dummy gate 202 and block 1020 etches away the recessed layers of condensed sacrificial material 402 that resulted from forming the dielectric layers 404. Block 1022 then forms a gate stack on the exposed surfaces of the layers of channel material 104, for example by forming a high-k dielectric layer 902 and a gate conductor by any appropriate conformal deposition process (e.g., CVD). Block 1024 forms a passivating layer (not shown) over the gate stack and source/drain structures 702. Block 1026 forms electrical contacts (not shown) to the source/drain structures 702 and the gate conductor 904 by etching holes through the passivating layer and depositing an appropriate conductive material.

Having described preferred embodiments of low-k dielectric inner spacer for gate all around transistors (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims.

Having thus described aspects of the invention, with the details and particularity required by the patent laws, what is claimed and desired protected by Letters Patent is set forth in the appended claims:

1. A method of forming a semiconductor device, comprising:
forming a stack of alternating channel layers and sacrificial layers;
recessing the sacrificial layers relative to the channel layers;
oxidizing ends of the sacrificial layers, after recessing the sacrificial layers, with a process that preferentially forms dielectric material on the sacrificial layers relative to the channel layers;
forming source and drain structures at ends of the channel layers;
etching away the sacrificial layers to expose surfaces of the channel layers; and
forming a gate stack on and around the channel layers.

2. The method of claim 1, wherein oxidizing ends of the sacrificial layers comprises a partial pressure of oxygen below 0.1 Torr to form a dielectric layer.

3. The method of claim 2, wherein oxidizing ends of the sacrificial layers comprises a temperature between 400° C. and 600° C.

4. The method of claim 2, wherein oxidizing ends of the sacrificial layers forms dielectric material on the sacrificial layers at a rate about seven times greater than a rate of forming dielectric material on the channel layers.

5. The method of claim 2, further comprising etching back the dielectric layer to expose ends of the channel layers.

6. The method of claim 5, wherein etching back the dielectric layer comprises an isotropic etch that selectively removes material from the dielectric layer.

7. The method of claim 2, wherein forming inner spacers further comprises nitridating the dielectric layer.

8. The method of claim 1, wherein forming inner spacers comprises forming the inner spacers with a flat interface with the sacrificial layers.

9. The method of claim 8, wherein the inner spacers are formed from silicon dioxide with a purity between 95% and 100%.

10. A method of forming a semiconductor device, comprising:
forming a stack of alternating channel layers and sacrificial layers;
recessing the sacrificial layers relative to the channel layers;
oxidizing the sacrificial layers and channel layers, after recessing the sacrificial layers, to form inner spacers at ends of the sacrificial layers from silicon dioxide with a purity between 95% and 100%;
forming source and drain structures at ends of the channel layers;
etching away the sacrificial layers to expose surfaces of the channel layers; and
forming a gate stack on and around the channel layers.

11. The method of claim 10, wherein oxidizing the sacrificial layers and channel layers comprises a partial pressure of oxygen below 0.1 Torr at a temperature between 400° C. and 600° C.

12. The method of claim 10, wherein oxidizing the sacrificial layers and channel layers comprises forming dielectric material on the sacrificial layers at a rate about seven times greater than a rate of forming dielectric material on the channel layers.

13. The method of claim 12, further comprising isotropically etching back the dielectric material to expose ends of the channel layers with an etch that selectively removes the dielectric material.

14. The method of claim 10, further comprising nitridating the dielectric inner spacers.

15. The method of claim 10, wherein oxidizing the sacrificial layers and channel layers forms the inner spacers with a flat interface with the sacrificial layers.

16. A semiconductor device, comprising:
a plurality of vertically stacked channel layers;
inner spacers positioned between vertically adjacent channel layers; and
a gate stack formed between and around the channel layers, where an interface between each inner spacer and the gate stack is flat.

17. The semiconductor device of claim 16, wherein the inner spacers are formed from silicon dioxide with a purity between about 95% and about 100%.

18. The semiconductor device of claim 16, wherein the inner spacers are formed from silicon oxynitride with a purity between about 95% and about 100%.

19. The semiconductor device of claim 16, further comprising inner spacers above a topmost channel layer and between a bottommost channel layer and a substrate.

20. The semiconductor device of claim 16, wherein each inner spacer has a horizontal width of about 6 nm.
